(19) United States
(12) Patent Application Publication
(10) Pub. No.: US 2026/0171127 A1
(43) Pub. Date: Jun. 18, 2026

(54) MEMORY READ OUT CIRCUIT

(71) Applicant: EMEMORY TECHNOLOGY INC., HSINCHU (TW)

(72) Inventors: CHIA-FU CHANG, HSINCHU COUNTY (TW); CHIA-CHING LI, HSINCHU COUNTY (TW)

(21) Appl. No.: 19/413,714

(22) Filed: Dec. 9, 2025

Related U.S. Application Data
(60) Provisional application No. 63/734,217, filed on Dec. 16, 2024.

(51) Int. Cl. G11C 7/10; G11C 5/14; G11C 7/22; H03K 19/20

(52) U.S. Cl. CPC G11C 7/1069; G11C 5/145; G11C 7/222; H03K 19/20

(57) ABSTRACT

A memory read out circuit includes a sensing module, an output module, and a voltage boost unit. The sensing module is configured to sense a data stored in a memory cell to generate an output data signal according to a first supply voltage. The output module includes buffers and configured to output the output data signal stably. The voltage boost unit is configured to provide the first supply voltage to at least one of the buffers before the sensing module begins to sense the data, and provide a second supply voltage greater than the first supply voltage to the at least one of the buffers when the sensing module senses the data so as to raise a reading speed of the memory read out circuit.

### CROSS-REFERENCE TO RELATED APPLICATIONS

This application claims the benefit of priority to U.S. Provisional Application Ser. No. 63/734,217, filed Dec. 16, 2024, which is incorporated by reference in its entirety.

### TECHNICAL FIELD

The present application relates to a memory read out circuit, particularly a memory read out circuit able to boost a supply voltage for an output module of the memory read out circuit.

### BACKGROUND

Memory reading speed is a critical parameter in memory device. The reading speed is associated with the supplied power. However, in some situations, the supplied power may not sufficient to a read out circuit to read the data with a required reading speed. Therefore, how to control the reading speed in the memory device is an important issue in this field.

### SUMMARY OF THE INVENTION

Some embodiments of the present disclosure provide a memory read out circuit includes a sensing module, an output module, and a voltage boost unit. The sensing module is connected to a first supply voltage and configured to sense a data stored in a memory cell to generate an output data signal according to a first enable signal. The output module is coupled to the sensing module and configured to output the output data signal stably. The voltage boost unit is configured to provide the first supply voltage to at least one of the buffers of the output module before the sensing module begins to sense the data,
and provide a second supply voltage greater than the first supply voltage to the at least one of the buffers when the sensing module senses the data so as to raise a reading speed of the memory read out circuit.

The memory read out circuit of the present disclosure is able to boost a supply voltage when the read out operation is performed, so as to improve the reading speed compared to the known techniques.

### BRIEF DESCRIPTION OF THE DRAWINGS

FIG. 1 is a schematic diagram of a memory read out circuit according to some embodiments of the present disclosure.

FIG. 2 is a schematic diagram of a memory read out circuit in detail according to some embodiments of the present disclosure.

FIG. 3 is waveforms of signals transmitted a memory read out circuit according to some embodiments of the present disclosure.

FIG. 4 is a schematic diagram of a memory read out circuit in detail according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately,” or “about” generally mean within a value or range which can be contemplated by people having ordinary skill in the art. Alternatively, the terms “substantially,” “approximately,” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately,” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

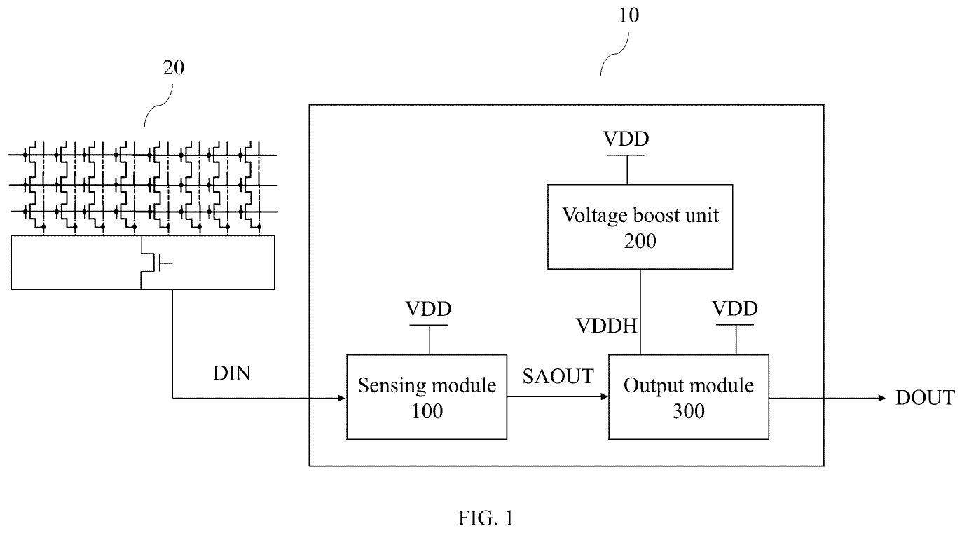

FIG. 1 is a schematic diagram of a memory read out circuit 10 according to some embodiments of the present disclosure. The memory read out circuit 10 is coupled to a memory array 20 and configured to sense a data DIN stored in a memory cell of the memory array 20. The memory read out circuit 10 is further configured to generate an output data signal DOUT according to the data DIN.

The memory read out circuit 10 includes a sensing module 100, a voltage boost unit 200, and an output module 300. The sensing module 100 is configured to sense the data DIN and generate a sensed data signal SAOUT according to the data DIN. The output module 300 is configured to receive the sensed data signal SAOUT from the sensing module 100 and transmit the sensed data signal SAOUT to an output terminal of the output module 300 to be the output data signal DOUT. The voltage boost unit 200 is coupled to the output module 300 and configured to provide a supply voltage VDDH to the output module 300. The supply voltage VDDH is variable according to the operation of the voltage boost unit 200. Specifically, the voltage boost unit 200 may adjust the supply voltage VDDH according to the operation of the memory read out circuit 10 so as to allow the output module 300 to have a higher reading speed when needed.

The sensing module 100 and the voltage boost unit 200 are operated under the supply voltage VDD. In some embodiments, the supply voltage VDD is a constant. In some embodiments, the output module 300 is operated under the supply voltage VDD when the voltage boost unit 200 provides the supply voltage VDDH equal to the supply voltage VDD. In some embodiments, the output module 300 is operated under the supply voltage VDD and the supply voltage VDDH different from the supply voltage VDD. In some embodiments, the supply voltage VDDH is greater than or equal to the supply voltage VDD.

The memory read out circuit 10 has a nominal supply voltage. However, in some cases, the supply voltage VDD may be less than the nominal supply voltage, and a reading speed of the memory read out circuit 10 may be slower and fail to meet the requirement. In order to ensure that the reading speed can satisfy the requirement, the voltage boost unit 200 is configured to provide the supply voltage VDDH greater than the supply voltage VDD to the output module 300 when the memory read out circuit 10 is sensing the data DIN. In some embodiments, the supply voltage VDDH is greater than the nominal supply voltage.

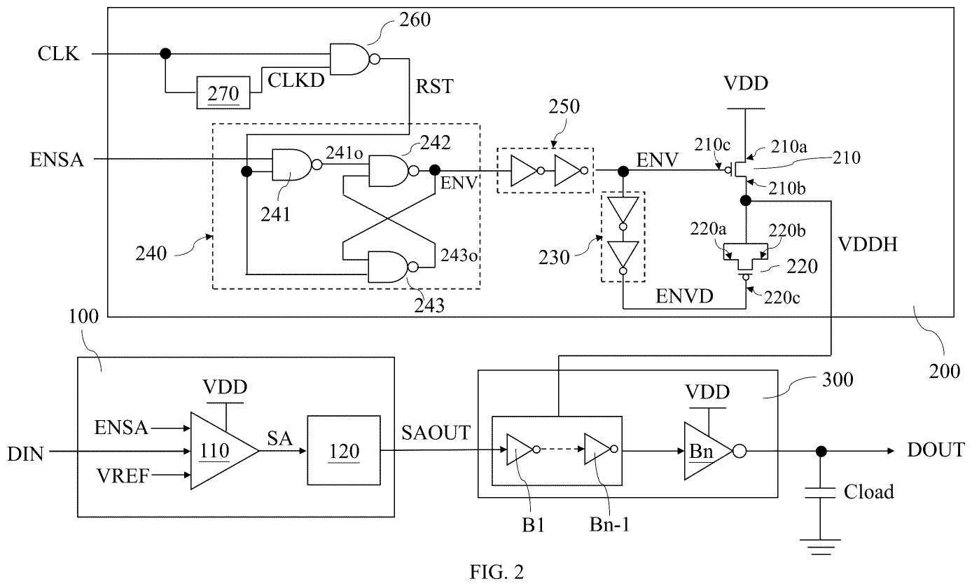

Reference is made to FIG. 2. FIG. 2 is a schematic diagram of the memory read out circuit 10 in detail according to some embodiments of the present disclosure.

The sensing module 100 includes a sensing amplifier 110 and a latch 120. The sensing amplifier 110 is operated under the supply voltage VDD and a reference voltage VREF, and is configured to sense the data DIN by comparing the data DIN with the reference voltage VREF so as to generate a sensed data SA. In some embodiments, the sensed amplifier 110 is enabled by an enable signal ENSA, wherein the enable signal ENSA is generated by delaying a clock signal CLK. In some embodiments, the clock signal CLK is a read clock provided by a device external to the memory read out circuit 10.

The latch 120 is configured to latch the sensed data SA to be the sensed data signal SAOUT. In some embodiments, the latch 120 is configured to provide a longer hold time for the output module 300 to read the sensed data SA, hence, the latch 120 latches the sensed data SA to be the sensed data signal SAOUT, so as to prevent the signal dropping too early to sense.

In some embodiments, the output module 300 includes n buffers and designated as B1 to Bn-1 and Bn, wherein n is an integer and greater than 1. The buffers B1 to Bn are in series connection. The buffer B1 is configured to receive the sensed data signal SAOUT from the latch 120. The buffer Bn is connected to an output terminal of the output module 300, wherein the buffer Bn is the last buffer and closest to the output terminal of the output module 300 among the buffers B1 to Bn.

In some embodiments, the power (i.e., the supply voltage VDDH) of the buffers B1 to Bn-1 is supplied through the voltage boost unit 200, and the power of the buffer Bn is provided by the supply voltage VDD. In other embodiments, the voltage boost unit 200 provides the power to fewer buffers, and more than one buffers are powered by the supply voltage VDD.

A capacitor Cload coupled to the output terminal of the output module 300 represents an output loading when the output data signal DOUT is outputting from the memory read out circuit 10.

The voltage boost unit 200 includes a switch 210, a capacitor 220, a delay module 230, a latch module 240, a buffer 250, a NAND gate 260, and a delay module 270.

The switch 210 includes a first terminal 210a, a second terminal 210b, and a control terminal 210c. The first terminal 210a is coupled to the supply voltage VDD. The second terminal 210b is coupled to and configured to provide the supply voltage VDDH to the output module 300. The control terminal 210c is configured to receive an enable signal ENV. The capacitor 220 is coupled between the second terminal 210b and the control terminal 210c. The delay module 230 is coupled between the control terminal 210c and the capacitor 220.

The switch 210 is turned on and off in response to the enable signal ENV. When the switch 210 is turned on in response to the first enable signal ENV, the supply voltage VDD is transmitted to the second terminal 210b, and the second terminal 210b is configured to provide the supply voltage VDD to the output module 300. Namely, when the switch 210 is turned on in response to the first enable signal ENV, the supply voltage VDDH is equal to the supply voltage VDD. When the switch 210 is turned off in response to the first enable signal ENV, the second terminal 210b is configured to provide the supply voltage VDDH greater than the supply voltage VDD to the output module 300.

In some embodiments, the switch 210 is implemented by a P channel metal-oxide-semiconductor field effect transistor (PMOS). The first terminal 210a is a source/drain of the PMOS, the second terminal 210b is an another source/drain of the PMOS, and the control terminal 210c is a gate of the PMOS. In these embodiments, when the enable signal ENV has a logic high level, the switch 210 is turned off; and when the enable signal ENV has a logic low level, the switch 210 is turned on.

The delay module 230 is configured to delay the enable signal ENV to be a delayed enable signal ENVD, and transmit the delayed enable signal ENVD to the capacitor 220. In some embodiments, the delay module 230 include even number of inverters in series connection, such as two inverter.

The capacitor 220 has a first terminal 220a, a second terminal 220b, and a control terminal 220c. In some embodiments, the capacitor 220 is implemented by a PMOS. The first terminal 220a, the second terminal 220b, and the control terminal 220c are a source, a drain, and a gate of the PMOS. The first terminal 220a and the second terminal 220b connected to each other are coupled to the second terminal 210b of the switch 210. The control terminal 220 c is opposite to the first terminal 220a and the second terminal 220 b, and coupled to the delay module 230.

When the switch 210 is turned on in response to the first enable signal ENV having a logic low level, the first terminal 220a and the second terminal 220b receive the supply voltage VDD, and the control terminal 220c responds to have the logic low level. When the switch 210 is turned off in response to the first enable signal ENV having a logic high level, the capacitor 220 is charged and starts to accumulate additional charges, and thereafter the voltage on the first terminal 220a and the second terminal 220b is boosted to a level equal to the supply voltage VDD plus the charged voltage accumulated on the capacitor 220. Accordingly, the supply voltage VDDH, output from the terminal 210b, is raised to a level greater than the supply voltage VDD.

The enable signal ENV is generated by the latch module 240, and the buffer 250 is configured to transmit the enable signal ENV to the control terminal 210c of the switch 210 and the delay module 230. In some embodiments, the buffer 250 includes even number of inverters in series connection, such as two inverters.

The latch module 240 is configured to generate the enable signal ENV in response to the enable signal ENSA and a reset signal RST. When the latch module 240 receives the enable signal ENSA having the logic high level pulse, the latch module 240 generates the enable signal ENV and latches the enable signal ENV to have the logic high level until the latch module 240 receives the reset signal RST having the logic high level pulse. In other words, a period of the enable signal ENV having the logic high level starts from receiving the logic high pulse of the enable signal ENSA until receiving the logic high pulse of the reset signal RST. The reset signal RST is configured to reset the enable signal ENV, more particularly, when the reset signal RST having the logic high level pulse is received, it makes the enable signal ENV have the logic low level. That is to say, the enable signal ENV is set to the logic high level in response to the logic high level pulse of the enable signal ENSA and is set to the logic low level in response to the logic high pulse of the reset signal RST. The latch module 240 includes a NAND gate 241, a NAND gate 242, and a NAND gate 243. The NAND gate 241 is configured to receive the enable signal ENSA and the reset signal RST, and perform a NAND operation on the enable signal ENSA and the reset signal RST to generate a first logic output 241o. The NAND gate 242 is configured to receive the first logic output 241o and a third logic output 243o, and perform the NAND operation on the first logic output 241o and the third logic output 243o to generate the enable signal ENV. The NAND gate 243 is configured to receive the enable signal ENV and the reset signal RST, and perform the NAND operation on the enable signal ENV and the reset signal RST to generate the third logic output 243o. The NAND gate 242 and the NAND gate 243 is collectively configured as a latch.

The NAND gate 260 is configured to receive the clock signal CLK and a delay clock signal CLKD, and perform the NAND operation on the clock signal CLK and the delay clock signal CLKD to generate the reset signal RST. The delay module 270 is configured to delay the clock signal CLK so as to generate the delay clock signal CLKD. Thereafter the NAND gate 260 starts to output the reset signal RST having the logic high level pulse in response to receiving a rising edge of the clock signal CLK.

Based on the structure of the memory read out circuit 10, the voltage boost unit 200 is configured to provide the supply voltage VDDH that is substantially equal to the supply voltage VDD to at least one buffers B1 to Bn-1 before the sensing module 100 begins to sense the data DIN, and provide the supply voltage VDDH greater than the supply voltage VDD to at least the at least one buffers B1 to Bn-1 when the sensing module 100 senses the data DIN so as to raise the reading speed of the memory read out circuit 10.

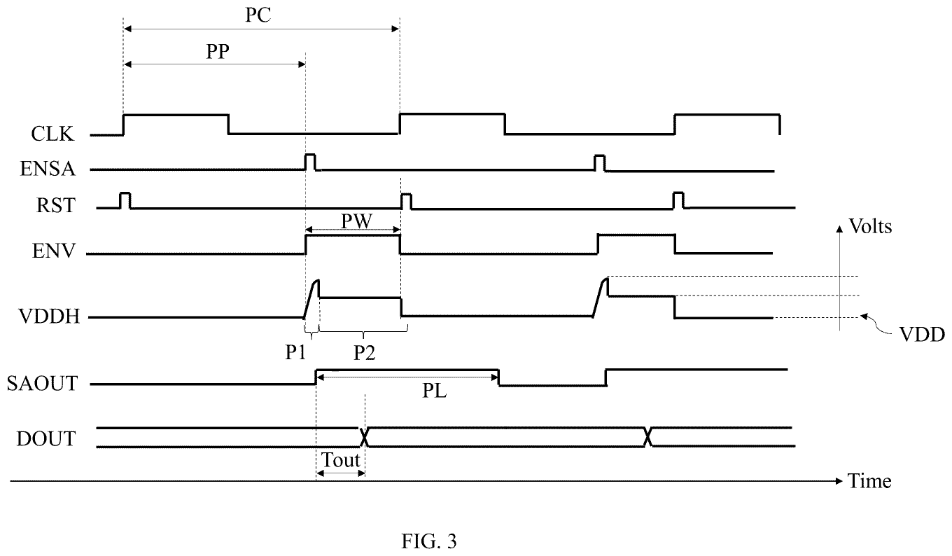

Reference is made to FIG. 3. FIG. 3 is waveforms of signals transmitted in the memory read out circuit 10 according to some embodiments of the present disclosure. The waveforms in FIG. 3 includes the clock signal CLK, the enable signal ENSA, the reset signal RST, the enable signal ENV, the supply voltage VDDH, the sensed data signal SAOUT, and output data signal DOUT.

In some embodiments, the clock signal CLK is a read clock provided by a device external to the memory read out circuit 10. The reset signal RST generates a synchronous reset pulse that is sampled on the rising edge of the clock signal CLK. The enable signal ENSA is generated by delaying the rising edge of the clock signal CLK by a predetermined period PP. The predetermined period PP is less than a period PC of the clock signal CLK. That is to say, the enable signal ENSA is designed to enable the sensing module 100 before the next read clock cycle of the clock signal CLK.

When the enable signal ENSA has the logic high level pulse, the sensing module 100 starts to sense the data DIN, and the sensed data signal SAOUT is generated and latched for a period PL.

The enable signal ENV is asserted starting from the enable signal ENSA having the logic high level pulse until the reset signal RST having the logic high level pulse. A pulse width PW of the enable signal ENV corresponds to the time interval between a rising edge of the logic high pulse of the enable signal ENSA and the first rising edge of the logic high pulse of the reset signal RST after the rising edge of the enable signal ENSA.

Before the enable signal ENV is asserted (i.e., while it remains at the logic low level), the switch 210 is turned on accordingly, and the supply voltage VDDH provided to the output module 300 has the level of the supply voltage VDD. During the asserted duration of the enable signal ENV, the supply voltage VDDH starts to be raised from the supply voltage VDD when the enable signal ENSA has the logic high level pulse, and the supply voltage VDDH drops back to the level of the supply voltage VDD when the reset signal RST has the logic high level pulse. Moreover, the supply voltage VDDH is boosted from the supply voltage VDD due to charging of the capacitor 220. In some embodiments, the capacitor 220 is carefully designed to ensure that the supply voltage VDDH can be boosted to a target voltage level suitable for the intended circuit operation. The target voltage level may vary depending on design choices and application requirements. In one embodiment, a capacitance of the capacitor 220 is associated with a number of the plurality of buffers (i.e., the number n of the reference numeral in Bn).

Therefore, the supply voltage VDDH in the first duration P1 is boosted from the supply voltage VDD to a higher voltage level (may be higher than the target voltage). The supply voltage VDDH in the second duration P2 is then dropped to the target voltage level substantially equal to a sum of the supply voltage VDD and a turn-on voltage of a P-N junction of the PMOS. For example, when the delayed enable signal ENVD is changed from the logic low level (e.g., the ground voltage or 0V) to the logic high level for turning off the switch 210, then the supply voltage VDDH on the first terminal 220a and the second terminal 220 b may be raised to 1.6 times the supply voltage VDD (e.g., 0.8V) instantly, however, the supply voltage VDDH may be discharged through the switch 210, so the supply voltage VDDH may be dropped to a voltage level (e.g., 1.2V) equal to the supply voltage VDD plus the turn-on voltage of the P-N junction of the PMOS of the switch 210 as the swtich 210 is finally turned off.

Furthermore, the sensed data signal SAOUT should be held for a sufficient time for the output module 300 reading out. As shown in FIG. 3, the latched period PL is greater than the pulse width PW of the enable signal ENV, so as to ensure that the sensed data signal SAOUT stays stable during the entire reading window of the output module 300.

In addition, a reading time Tout is defined between the output module 300 receiving the sensed data signal SAOUT and outputting the output data signal SOUT. Due to the supply voltage VDDH provided by the voltage boost unit 200, the reading time Tout is shorter than a reading time without the voltage boost unit 200.

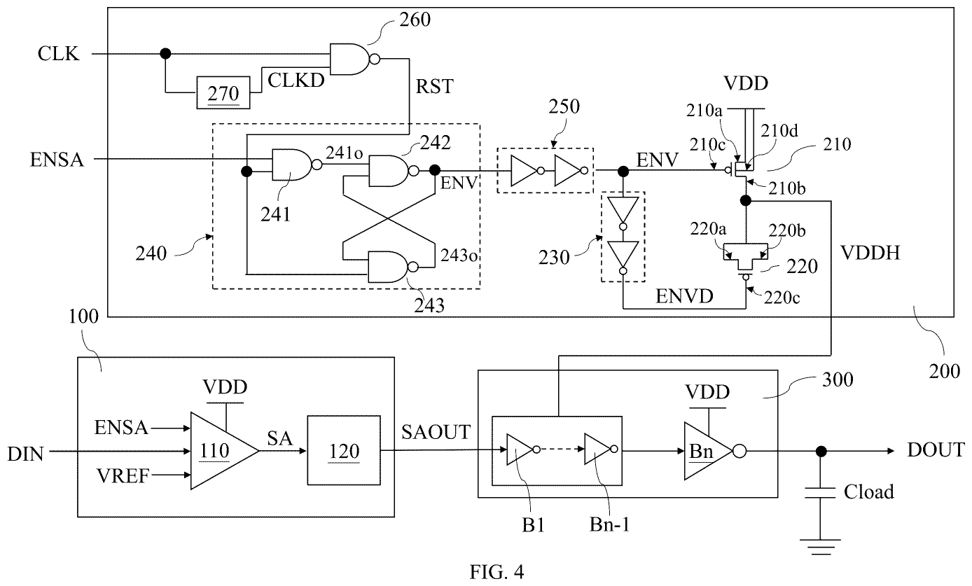

FIG. 4 is a schematic diagram of a memory read out circuit in detail according to other embodiments of the present disclosure. In some embodiments, the switch 210 further includes a third terminal 210d as shown in FIG. 4. The third terminal 210d is a body of the PMOS, and the third terminal 210d is coupled to the first terminal 210a and the supply voltage VDD. The switch 210 thus may additionally function as a voltage clamp. When the third terminal 210d (the body of the PMOS) is coupled to the supply voltage VDD, an voltage of the supply voltage VDDH in the first portion P1 can be limitted to about a sum of the supply voltage voltage plus a turn-on voltage of a P-N junction of the PMOS due to the clamping effect of the switch 210. After the enable signal ENV drops to the logic low level, the switch 210 is turned on, and the supply voltage VDDH drops back to the supply voltage VDD. In some embodiments, the supply voltage VDDH may drop to a voltage lower than the supply voltage VDD and bounce back to the supply voltage VDD. However, the delay module 230 allows the switch 210 to be turned on before the supply voltage VDDH is coupled to a lower voltage by the capacitor 220 instantly, thereby decreasing the amount of the dropping of the supply voltage VDDH.

The foregoing outlines features of several embodiments so that those skilled in the art may better understand various aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent embodiments still fall within the spirit and scope of the present disclosure, and they may make various changes, substitutions, and alterations thereto without departing from the spirit and scope of the present disclosure.

What is claimed is:

1. A memory read out circuit, comprising:
a sensing module connected to a first supply voltage, configured to sense a data stored in a memory cell to generate an output data signal according to a first enable signal;
an output module coupled to the sensing module, comprising a plurality of buffers and configured to output the output data signal stably; and
a voltage boost unit, configured to provide the first supply voltage to at least one of the plurality of buffers before the sensing module begins to sense the data, and provide a second supply voltage greater than the first supply voltage to the at least one of the plurality of buffers when the sensing module senses the data so as to raise a reading speed of the memory read out circuit.

2. The memory read out circuit of claim 1, wherein the voltage boost unit comprises:
a switch, having a first terminal, a second terminal, and a control terminal, wherein the first terminal is coupled to the first supply voltage, the second terminal is coupled to the output module, and the control terminal is configured receive a second enable signal; and
a capacitor, coupled between the second terminal of the switch and the control terminal of the switch,
wherein when the switch is turned off in response to the second enable signal, the second terminal of the switch is configured to provide the second supply voltage to the output module, and
wherein when the switch is turned on in response to the second enable signal, the second terminal of the switch is configured to provide the first supply voltage to the output module.

3. The memory read out circuit of claim 2, wherein the voltage boost unit further comprises:
a first delay module, coupled between the capacitor and the control terminal of the switch, wherein the second enable signal is transmitted from the control terminal of the switch to the capacitor through the first delay module.

4. The memory read out circuit of claim 2, wherein the voltage boost unit further comprises:
a latch module, configured to generate the second enable signal in response to the first enable signal and a reset signal,
wherein when the latch module receives the first enable signal having a logic high level pulse, the latch module generates the second enable signal and latches the second enable signal to have the logic high level until the latch module receives the reset signal having the logic high level pulse, and
wherein after the latch module receives the reset signal having the logic high level pulse, the latch module generates the second enable signal having a logic low level.

5. The memory read out circuit of claim 4, wherein the voltage boost unit further comprises:
a buffer, coupled between the latch module and the control terminal of the switch.

6. The memory read out circuit of claim 5, wherein the latch module comprises:
a first NAND gate;
a second NAND gate; and
a third NAND,
wherein the first NAND gate is configured to generate a first logic output according to the frist enable signal and the reset signal, and transmit the first logic output to the second NAND gate,
wherein the second NAND gate is configured to generate the second enable signal according to the first logic output and a third logic output generated by the third NAND gate, and transmit the second enable signal to the buffer, and
wherein the third NAND gate is configured to generate the third logic output according to the reset signal and the second enable signal.

7. The memory read out circuit of claim 4, wherein the voltage boost unit further comprises:
a NAND gate, configured to generate the reset signal in response to a first clock signal and a second clock signal; and
a second delay module, configured to delay the first clock signal so as to generate the second clock signal.

8. The memory read out circuit of claim 7, wherein the first enable signal is generated by delaying the reset signal.

9. The memory read out circuit of claim 2, wherein the switch is a P channel metal-oxide-semiconductor field-effect transistor (PMOS),
wherein the first terminal, the second terminal, and the control terminal are a first source/drain, a second source/drain, and a gate of the PMOS, respectively.

10. The memory read out circuit of claim 9, wherein the switch further comprises a third terminal coupled to the first terminal of the switch,
wherein the third terminal is a body of the PMOS.

11. The memory read out circuit of claim 9, wherein the second supply voltage is equal to a sum of the first supply voltage and a turn-on voltage of a P-N junction of the PMOS.

12. The memory read out circuit of claim 2, wherein the capacitor is a PMOS, wherein a gate of the PMOS is coupled to the control terminal of the switch, and a first source/drain and a second source/drain of the PMOS are coupled to the second terminal of the switch.

13. The memory read out circuit of claim 2, wherein a capacitance of the capacitor is associated with a number of the plurality of buffers.

14. The memory read out circuit of claim 1, wherein the second supply voltage is greater than a nominal supply voltage of the memory read out circuit.

15. The memory read out circuit of claim 1, wherein when the second supply voltage is provided to the at least one of the plurality of buffers, a last buffer of the plurality of buffers is provided by the first supply voltage,
wherein the last buffer is closest to an output terminal of the output module among the plurality of buffers.
